(19) United States
(12) Patent Application Publication
(10) Pub. No.: US 2008/0248230 A1
(43) Pub. Date: Oct. 9, 2008

(54) Polymer Emi Housing Comprising Conductive Fibre

(75) Inventors: Rik Dewitte, Oudenaarde (BE); Wim Verbrugge, Pittem (BE); Stefaan De Bondt, Heestert (BE); Paul Abraham Willems, AG Den Haag (NL); Robert Frans Brounne, LB Halsteren (NL)

Correspondence Address: FOLEY AND LARDNER LLP;SUITE 500, 3000 K STREET NW, WASHINGTON, DC, 20007, US

(73) Assignees: NV BEKAERT SA, Zwevegem (BE); SABIC INNOVATIVE PLASTICS BV, Bergen op Zoom (NL)

(21) Appl. No.: 11/915,954

(22) PCT Filed: Feb. 3, 2006
(86) PCT No.: PCT/EP2006/050645

§ 371 Date: Feb. 20, 2008

(30) Foreign Application Priority Data
Jun. 2, 2005 (EP) 05104802.3

(51) Int. Cl. H05K 9/00; B29C 45/00

(52) U.S. Cl. 428/36.4; 428/206; 428/143; 428/208; 264/104

(57) ABSTRACT

An electromagnetic shielding housing is presented that is made up out of one or more shells. The shells comprise polymer and conductive fibres and have a polymer rich surface that covers the fibres except for predefined areas where the fibres are substantially uncovered. The conductive fibres can be metal-coated non-metallic fibres or plain metallic fibres, preferably plain stainless steel fibres. A method for uncovering the fibres is also presented which comprises the breaking-off of selected protrusions or the breaking of the shell at selected recesses so as to uncover the fibres. The housing and the method solve the problem that the polymer skin leads to inferior shielding at the joint of the shells.

### FIELD OF THE INVENTION

The present invention relates to housings that abate electromagnetic interference (EMI) by absorbing or reflecting electromagnetic waves. The housings are assembled out of one or more shells that neatly match together. At least one of the shells is made from a polymer material wherein electrically conductive fibres are dispersed. The fibres are arranged such that contact between fibres of different shells is optimised. The invention is also extended to a method to produce such a shell.

### BACKGROUND OF THE INVENTION

As the electromagnetic (EM) environment is more and more polluted with radiation of an ever increasing number of electronic appliances working at more and more dispersed frequencies, the need increases for housings that on the one hand keep the radiation emitted by an electronic device inside the housing while on the other hand prevent outside radiation to disturb the functioning of the device. This housing therefore must at least reflect the electromagnetic radiation and preferably absorb it, the sum of both being generally referred to as the ‘shielding efficiency’ (SE) of the housing. Absorption is more preferred as it prevents the mutual disturbance of different components mounted inside the housing on different printed circuit boards (PCB), something that could occur when the housing is only reflecting. As the housing of the device also has to fulfil other than purely electromagnetic requirements such as an economy of price, sturdiness and shock absorbance, weight or rather the lack of it, and not to forget the freedom to give the appliance an appealing design it is clear that a metal box is not the best solution even given its superior shielding performance.

Polymers and more in particular thermoplastic polymers have an attractive range of properties for the appliance housing designer: they are relatively cheap, they can easily be coloured, they have good shock absorbing properties and can be cost effectively produced in an injection-molding device in almost any conceivable form at a high production rate. A housing can then be assembled out of injection-molded shells that snap fit together. Also a single shell can be used to make a housing provided it has a bendable seam to fold it together. Unfortunately thermoplastic polymers are insulators and have no shielding properties. These can be added to the shells after the production of the shell by e.g. coating the inside with a metal paint or by evaporation metalisation or electroless metal plating or any other technique. But this is an additional operation making the product more expensive. One has therefore sought to make polymeric housings conductive by adding conductive fillers to the compound with which such housings are made. Popular filler materials are carbon blacks, carbon fibres, carbon nanotubes (see e.g. US 03/013199), metallic flakes, such as flakes from zinc, nickel, aluminium or alloys like stainless steel, or electrically conduction fibres such as nickel coated carbon fibres or nickel coated glass fibres or plain metal fibres such as stainless steel fibres (as per U.S. Pat. No. 5,397,608). Many types of mixtures thereof have also been proposed as in e.g. WO 93/227 744, U.S. Pat. No. 6,685,854, U.S. Pat. No. 4,596,670 to name just few.

Especially electrically conducting fibres are preferred as their length to diameter ratio promotes the formation of percolating networks throughout the injection-molded housing. In addition they tend to absorb better the radiation due to their matching electrical resistance, as they are extremely fine. The mixture of fibres and granules can be provided in the form of:
fibre granules added to the polymer granules. A fibre granule is a short bundle of fibres, held together by an outer jacket of the polymer of the housing or a polymer compatible with it. Jacketing can be done through extrusion or pulltrusion of the bundle. The appropriate amount of granules have then to be mixed with the polymer granules to obtain the correct masterbatch. The masterbatch is then used to produce the housing, or
as a ‘compound’ which is in essence an extrudate of the above masterbatch (i.e. with the final ratio of polymer and fibre contact) into monofilaments (3 to 5 mm in diameter) that are subsequently chopped. The compound granules can be used as is and no further mixing is then necessary.

Injection-molded shells made from such a ‘masterbatch’ or ‘compound’ show good bulk shielding efficiency (SE) as is e.g. demonstrated in US 4664971. However, electrically conductive fibres turn out to have a major drawback. As the fibres are entrained by the plasticised polymer into the mold, they follow the polymer. Hence at the borders of the mold where the polymer flow is stopped, there is a relative lack of fibres. Also the fibres tend to be less present at the surface of the shell as they are not held by the mold—contrary to the polymer that solidifies when contacting the cooled mold—and are therefore drawn by the liquid polymer towards the inside of the shell. These effects lead to the formation of a polymer skin, about 50 to 500 μm thin, at the surface of the shell. While the above does not affect the bulk SE, it does affect the overall shielding efficiency of the housing because when shells are assembled together a discontinuity in the fibre network occurs there where the edges of the shell touch one another i.e. at the joint. Hence although the joint between the shells is visibly tight, there is an electrical discontinuity due to the polymer skin. This discontinuity results in an electromagnetic radiation gap through which radiation escapes. Moreover, as the gap is generally long and thin, it will act as a slot antenna. The polymer skin at the surface of the shell therefore leads to a ‘contacting problem’.

A first solution to the contacting problem is the use of a groove and tongue joint. Depending on the depth of the groove and the width of the tongue, the total overlap can be controlled. This ‘overlap method’ provides a reasonable solution for frequencies above 300 MHz as the overlap provides a low impedance that is entirely capacitive in nature so that the gap appears as a short circuit to the electromagnetic waves. For lower frequencies, there remains a problem in that the contact resistance between the shells at the overlap is too high and the overlap acts as a slot antenna.

Also the use of the state-of-the-art gaskets in the overlap does not improve the SE in the range between DC to 500 MHz. Special gaskets with protruding conductive pins have been proposed in U.S. Pat. No. 6,818,822 (considered to be the closest prior-art) to bridge insulating gaps as a consequence of for example painting or oxidation of a cabinet. Although this type of gasket may certainly help in the case of a thin insulating layer covering a highly conductive housing of reasonable magnitude, it remains to be verified whether the solution would also work in e.g. a handheld telephone set, as the pins would have to be correspondingly smaller and thus would loose their mechanical strength to penetrate the polymer. The inventors therefore set themselves the task to resolve the problems left by the prior-art.

### SUMMARY OF THE INVENTION

The main object of the invention is therefore to improve on the prior-art. As such the first object of the invention is to provide for an easy-to-produce housing that has an improved shielding efficiency compared to the existing art. A further object of the invention is to provide a housing that largely resolves the ‘contacting problem’. Moreover, the invention resolves this problem over a wide frequency range between 10 MHz and 10 GHz. It is a further object of the invention to provide a method for implementing such housing. Moreover the method provides an efficient way to produce the housing without the need of much additional work or materials.

According a first aspect of the invention (independent claim 1), a shielding shell is provided. The shell comprises polymeric material and electrically conductive fibres. Such shells are known in the art. They can take a variety of dimensions: from the housing for an in-ear hearing aid, over the size of a handheld telephone, to the size of an electrical cabinet. For the purpose of this application, with a shell is meant a shape of substantially two dimensions with a small third dimension called thickness. The two dimensional shape is generally not flat and is mostly—although this need not always be so—formed into a shape defining a convex volume. Such shell has a surface that can be readily subdivided into an inner surface (towards the convex volume), an outer surface and edges. Moreover the shell may have none, one or more holes in it to accommodate e.g. a display, an indicator, buttons, antenna feedthroughs or the like. The shell must have a certain strength, density and hardness so as to fulfil the protective functionality expected from such a shell. The conductive fibres are dispersed throughout the polymer. However, as described in the ‘Background of the invention’, at the surface of the shell a polymer skin is present, because the flowing polymer entrains the conductive fibres. So the fibres are substantially covered by the polymer, which does not exclude the fact that randomly and rarely a single fibre may be uncovered at the surface. This can be quantified as the number of fibres per unit square that are visible at the surface. This number will of course depend on the ‘loading’ of the polymer i.e. the volume percentage of fibres relative to the total.

The inventive shell now discriminates itself from the existing prior-art in that on well-defined areas on the surface of the shell a large number of fibres are uncovered at the surface. With ‘uncovered’ is meant that an electrical contact with the conductive fibre is possible. With ‘large number’ is meant: more than are visible per unit square at the surface outside the predefined area. Note that not all visible fibres outside the defined areas are to be considered as uncovered as the polymers are slightly transparent, making the number difference between uncovered fibres per unit square inside the areas or outside the areas already much larger. More preferred is if more than two times as much fibres per unit square are uncovered in the defined areas than that there are fibres visible per unit square outside the areas. Most preferred is if there are more than ten times as much fibres uncovered per unit square in the predefined areas than that there are visible per unit square outside the areas. These well-defined areas may be on the inner surface, or may be at the edges or may be at the outer surface of the shell. The uncovered areas are defined during the design of the shell, as their position has to fit with the counterparts forming the overall housing.

The areas may coalesce to form one or more paths on the surface (dependent claim 2). These paths may be closed or not closed depending on the needs of the design. For example the conductive fibres at the edges of the shell may be uncovered. The edges of the shell are particularly difficult areas as explained before. Another area where uncovered fibres help to improve the shielding is at the rim of a feedthrough hole. Recesses of circular or rectangular or any other polygonal shape can define such a hole. The recesses can take the form of a continuous groove are can be segmented. As the recesses weaken the strength of the shell on these places, the shapes can be easily pushed through. In this way the conductive fibres are uncovered. The uncovered fibres can then, for example, electrically contact the shielding of a cable fed through the hole thus improving the overall shielding.

Although it is sufficient that the conductive fibres are uncovered, it is more preferred if a part of these uncovered fibres protrude out of the surface of the shell (dependent claim 3). Such protruding fibres facilitate the electric contact with fibres from the matching area even more.

Various types of electrically conductive fibres are possible. A first class of such fibres are glass fibres or carbon fibres that are coated with nickel or cupper or any other suitable high conducting material (dependent claim 4). Metallic fibres such as fibres made of any type of metal or metal alloy form a second class of materials. (dependent claim 5). Most preferred in this respect are stainless steel fibres in that they merge a good mechanical strength with oxidation resistance and electrical resistance (dependent claim 6). Preferred stainless steel alloys are AISI 300 or AISI 400-serie alloys, of which the most preferred ones are AISI 302. The AISI 302HQ family member as claimed in WO 03/010353 is most preferred due to its high strength in combination with a high elongation at break. Other types like AISI 316L or AISI 347 are also not excluded. Metal fibres can also be made of nickel or a nickel alloy. Such metal fibres may be made by any presently known metal fibre production method, e.g. by bundle drawing operation (yielding a predominantly five to seven sided fibre cross section), or by coil shaving operation as described in JP3083144 (yielding rectangular cross sections), by wire shaving operations (such as steel wool) or by a method providing metal fibres from a bath of molten metal alloy.

Metallic fibres preferably have an equivalent diameter between 1 μm and 50 μm and have an average length of between 0.5 mm and 50 mm (dependent claim 7). More preferred is if they have an equivalent diameter between 2 and 15 μm and an average length between 0.5 and 30 mm. The equivalent diameter of a metal fibre is that diameter of an imaginary circle having the same area as that of a transverse cross section of the fibre. The average length of the fibre is not necessarily the length of the fibre as mixed into the compound: during the mixing and subsequent injection molding, some of the fibres will be broken. In any case the average length of the fibres as they go into the compound sets an upper limit to the average length inside the compound.

The polymeric material is by preference a thermoplastic material that is suitable for injection molding. In addition the polymeric material must have sufficient strength and hardness so that it can meet the mechanical requirements of a protective shell. The following species and types (dependent claim 8 and 9) are preferred materials that can be used to produce the inventive shell:
polyolefines such as polypropylene (PP) or polyethylene (PE),
polyvinylchloride (PVC),
polystyrenes such as poly(acrylonitrile-butadiene-styrene) (ABS) or poly(styrene-acrylonitrile) (SAN) or High Impact polystyrene (HIPS),
thermoplastic polyurethanes (TPU's),
polyamides (PA's) such as PA 6 or PA 6.6,
polyphenylene sulphide (PPS),
polyesters such as polybutylene terephtalate (PBT), polyethylene terephtalate (PET),
polyacetals such as polyoxymethylene (POM),
polycarbonates (PC's),
polysulfones (PSU's) such as polyethersulfone (PES),
polyetherimides (PEI's),
Polyethylene ethers (PPE) such polyphenylene oxide (PPO® a trademark of General Electric),
Polyacrylics such polymethylmethacrylate (PMMA),
meltable polyimides and polyamide-imides,
polyetheretherketone (PEEK)
   Mixtures of the above materials are not excluded, as well as block- or copolymers of one or more polymers. Blends of polymers comprising one or more of the above mentioned polymers can also be used. The polymers can present in various forms such as homopolymers, copolymers and block copolymers. The person skilled in the art also knows that in order to use these material in an injection-molding machine, additives will have to be added such as plasticisers, flow agents, nucleation agents or the like. In addition pigments can be added to the compound mixture in order to give the shell a desired colour. Also other electrically active compounds can be added such as e.g. carbon fibres or carbon particles to improve on the Electro-Static Discharge (ESD) characteristics of the shell as suggested in US 2002/0145131A1.

According a second aspect of the invention, a shielding housing is provided, comprising one or more shells according the inventive shell (independent claim 10). Housings for electronic appliances are generally assembled out of one, two or more shells that can be fitted together by means of snap fittings, screws, bolts, clips, glues, or any other means known in the art to hold the shells together. A single shell can also be used when it is provided with a folding area so that by bending the shell at this folding area, a housing can be formed. Care must be exercised so that the conductive fibres in the folding area remain intact. The housing can also be of a hybrid nature in that certainly one of the shells is an inventive shell according claims 1 to 9 and the other shells are:
formed by (a part of) a printed circuit board
formed from metallic plates or foils
formed from metallic coated polymer sheet either post-formed or not post-formed in an appropriate shape as per WO 03/004261A1
formed from other materials as they are known in the art.
   Although the uncovered fibres need not make an electrical contact with the shell itself (in case the housing only comprises one shell) or with other shells, it is more preferred if they do (dependent claim 11). Indeed by improving the electrical contact between the fibres at the predefined areas, the impedance will be further reduced at the joint leading to an improved SE at even lower frequencies. The electrical contact of said uncovered fibres with one of the other shells or with the shell itself can be established through direct contact (dependent claim 12) between the fibres and e.g. other fibres in the same or another shell or with e.g. the conductive surface of the PCB or metallic shielding plate. The electrical contact can also be established through an intermediate conductor such as a gasket or a paste or a glue (dependent claim 13). Such a conductive gasket, paste or glue has the advantage that it provides a common conductor for all contacting fibres from both sides. In this way, the probability of electrical contact does not longer depend on the position of the uncovered fibre. Examples of gaskets are known in many forms and are made from—without being exhaustive—foams made conductive by coatings, or from foams surrounded by a conductive mesh, or from polymers loaded with conductive particles. Conductive pastes based on curable polymers like silicones loaded with a conductive material such as nickel flakes or carbon particles are likewise known and are used to form an ‘in situ’ gasket. Conductive glues are equally well available based on similar conduction mechanisms.

A particularly preferred type of shielding housing comprises two shells that can easily and repeatedly be jointed and released from one another thus establishing a pair of matching connectors (dependant claim 14). The connectors can be mechanically fitted to one another by means of a mating fit, or by means of a screw thread, or by means of a clamp or clip system, or a bayonet coupling, or by means of a snap fit, or by any other means commonly known in the art. At least one of the shells must have uncovered conductive fibres at the surface. E.g. an inlet socket on an electrical appliance (to plug the mains female connector into) can have conductive fibres on the inside while in particular areas the conductive fibres can make contact to the conductive housing of the appliance. Another example is a plug and socket combination. Both the housing of the plug and the socket comprise conductive fibres that on specific facing areas are uncovered. Upon mechanical interconnection, an electrical contact between the conductive fibres is also established (either by direct contact or through intermediation of a gasket). In this way the connection made inside the plug and socket combination can be shielded from external influences. Both the plug and socket can be provided with additional areas where the fibres are uncovered that come into contact with the outer shielding of the cable that goes into the plug or socket.

A third aspect of the invention concerns a method to produce the shielding shells (independent claim 15). As a first step in this method, a mixture of polymeric granules and electrically conductive fibres is made: the masterbatch. Alternatively the mixture of fibres and polymer can be provided in the form of polymer granules wherein the fibres are already present in the appropriate amount: the readymade compound (dependant claim 16). A volume percentage of 0.1% to 20% of conductive fibres is preferred. For stainless steel fibres this volume percentage can be significantly lower as per unit of volume occupied in the shell more conductive cross section is available compared to metal coated non-metallic fibres. For stainless steel fibres a volume percentage between 0.1 to 6% is preferred. Even more preferred is a volume percentage between 0.5 and 2% volume as this turns out to balance economic requirements with technological demands. When properly mixed, these percentages can be found back uniformly in the shell.

This mixture is dried prior to feeding into a hopper. The mixture is fed by gravity into the barrel of an injection-molding machine and is heated to the appropriate softening or processing temperature of the polymer. The softened polymer is then injected under the appropriate pressure by a reciprocating screw or a ram injector into the mold.

This mold is the negative of the shell to be formed. The mold is particular in that it defines specific protrusions and recesses on the shell, that on their turn define the areas on the surface of the shell where the conductive fibres will be uncovered. The mold must be so designed that it prevents or eliminates bubble formation in the shell, bubbles that could spoil the visual appearance and the strength of the shell.

The step of uncovering the fibres can be performed off-line after ejection and cooling down of the shell. More convenient is of course if the uncovering step occurs before or during ejection of the freshly made shell, as this eliminates the need for additional handling of the shell (dependent claim 17). The step of uncovering of the conductive fibres is preferably performed by breaking-off the protrusions or by breaking the shell at the predefined recesses (dependent claim 18). The protrusions as well as the recesses are so designed as to allow a clean breakage without burr, but with enough area uncovered to have a good joint. Recesses can be used to uncover the fibres at the edges. Or they can be used to form a push-through hole at a specific place. The uncovering step can either be done manually or by a robot. However, the operation of breakage is best introduced during the ejection of the shell. To this end injection-molding machines with double die pairs that can be independently moved relative to one another can be used.

Other methods for uncovering the fibres can of course also be used (dependent claim 19). Such methods can be cutting, grinding, buffing, filing, sawing, scraping, scratching or a combination thereof.

Other methods to manufacture the claimed shells or housings can of course also be envisaged. As examples the following methods are mentioned:
extrusion for example of the shielding shell of a cable
thermoforming readymade plates or sheets comprising polymer and fibres. The plates can be made by injection-molding, or the plates can be made by casting of polymer-fibre mixtures.
deepdrawing of readymade plates or sheets.
rotational molding in which the screw pressure is replaced by centrifugal forces.

### BRIEF DESCRIPTION OF THE DRAWINGS

The invention will now be described into more detail with reference to the accompanying drawings wherein

FIG. 1 ‘a’ shows a housing with its different elements

FIG. 1 ‘b’ shows a shell

FIG. 2 ‘a’ shows a cross section of the shell border prior uncovering of the fibres.

FIG. 2 ‘b’ shows a cross section of the shell border after uncovering.

FIG. 3 ‘a’ shows the joint of two shell borders with directly contacting fibres.

FIG. 3 ‘b’ shows the jointing of two shell borders with a conducting gasket in between.

FIG. 4 is a black-and-white picture of the edge of a shell.

FIG. 5 is a scanning electron microscope picture of the edge of a shell.

FIG. 6 shows the frequency dependent shielding efficiency of a joint according a first embodiment of the invention.

FIG. 7 shows the frequency dependent shielding efficiency of a joint according a second embodiment of the invention.

FIG. 8 shows the frequency dependent shielding efficiency of a joint according a third embodiment of the invention.

FIG. 9 shows a cross section of a plug and socket combination according the invention.

### DESCRIPTION OF THE PREFERRED EMBODIMENTS OF THE INVENTION

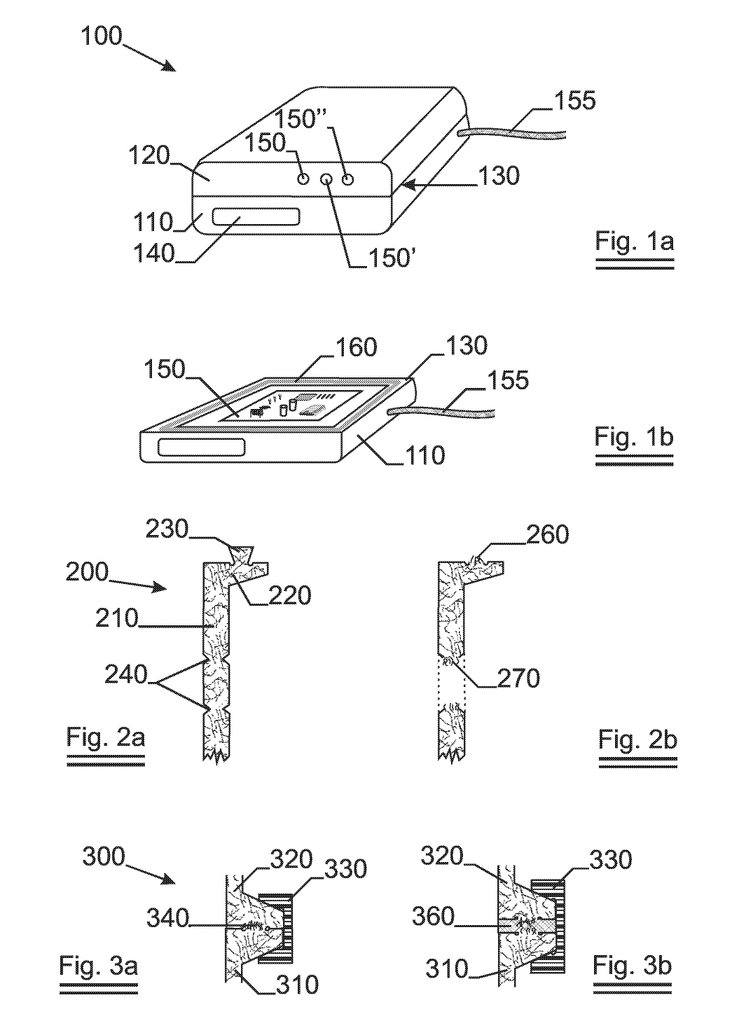

FIG. 1 is a schematic representation of a housing 100 for an electronic device 150 made out of two shells 110, 120. When both shells 110, 120 are matched against one another, a joint 130 is formed. The housing can comprise different apertures for example to accommodate a display 140, or to introduce control buttons or knobs 150, 150′, 150″ or to connect cables and feeds 155. At the borders of the shell that form the joint 130, a contacting area 160 is provided.

The internal structure of the shell is elucidated in FIG. 2 ‘a’. There a cross section 200 of a shell is shown. The electrically conductive fibres 210 are encapsulated in the polymeric material 220. A protrusion 230 in the form of a ridge at the border of the shell and a circular recess 240 are predefined in the shell during the design of the mold. Substantially all fibres are covered by polymeric material because the conductive fibres tend to avoid the surface of the shell. The conductive fibres can be uncovered by breaking-off the protrusions 230 or by pressing out the disc 250 as illustrated in FIG. 2 ‘b’. In this way a ‘brush’ of uncovered fibres 260, 270 forms that slightly protrude out of the surface. These brushes form excellent electrical contact points between the shells.

This electrical contact can be achieved for example by direct contact between the fibres from both shells as is shown in FIG. 3 ‘a’. There a cross section 300 of the joint is shown. A first shell 320 is directly clamped against the second shell 310 by means of clamp 330. The brushes of both shells 340 establish a good electrical contact and form a good joint. The jointing can even be further improved by the introduction of a gasket 360 as depicted in FIG. 3 ‘b’. It will be clear to the person skilled in the art that instead of a clamp, other attachment means can be used such as snap-on fixtures, screws or the like.

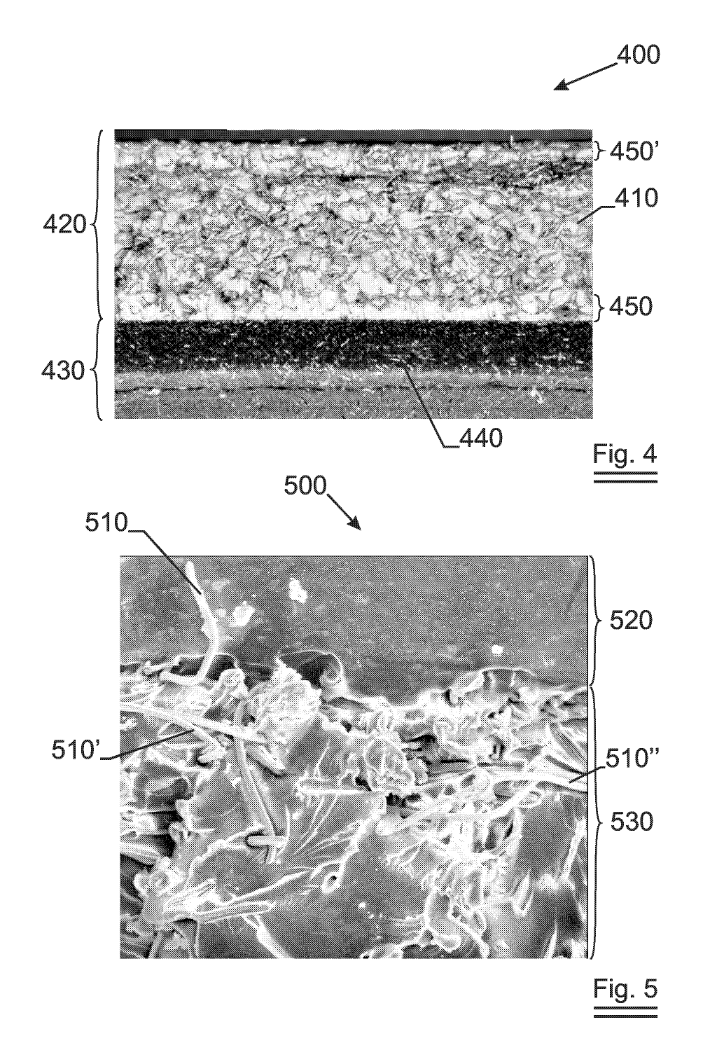

The uncovering of the fibres is further illustrated by means of FIG. 4. 400 is a reproduction of a photograph taken edge-on at the border of the shell. Two regions can be discerned: the area with the uncovered fibres 420—obtained by cracking of a ridge like 230—and the region with the surface of the shell 430 with the substantially covered fibres. Region 420 shows many fibres like 410 that are uncovered and protrude out of the area. Note also that sporadically fibres like 440 are visible in the region 430. However, this uncovering is by far not sufficient to establish a good joint between shells. Notice also that at the sides 450, 450′ nearer to the surface of the shell, there is a depletion of fibres. FIG. 5 essentially shows the same information but in more detail and with better focus as it is a scanning electron microscope picture 500. Again two regions can be discerned: 520 that is the surface of the shell containing the substantially covered fibres and 530 which is the area containing uncovered conductive fibres 510, 510′, 510″. The fibres in these pictures are stainless steel fibres with an equivalent diameter of 8 μm an average length of 5 mm. They were mixed in polycarbonate at a volume ratio of 2%.

A series of shells according the invention were made with different combinations of fibres and polymers. The shells were measured in line with the CISPR 22 (EN 55022) norm with the specifics mentioned below. The housing was made out of two shells measuring 17 cm×23 cm×6 cm fitted together to form a closed box, 12 cm high. Inside the box a circular magnetic loop antenna (diameter 30 mm, model 96021 from Eaton Corporation) was placed with the plane of the loop perpendicular to the joint of the shells. The centre of the loop was positioned at 3 cm from the 17 cm×12 cm side of the box, in the plane of the joint. The following equipment was used in the measurement:
Advantest TR4153A (100 kHz-2 Ghz) as tracking-generator
Advantest TR4131 (10 kHz-3.5 GHz) as spectrum analyser
ENI 603L (1 MHz-1 GHz) power amplifier
Logarithmic periodic (log-per) antenna
   Measurements were done in an anechoic room. The log-per antenna was placed at a distance of 3 meter. Prior to measurement a ‘no box’ swept-frequency (f) run was recorded as reference: Eₒ(f). After proper mounting of the jointed shells another run was recorded: E₁(f). Shielding effectiveness (expressed in dB) was then calculated as:

SE(f)=20 log₁₀(E₀/E₁)

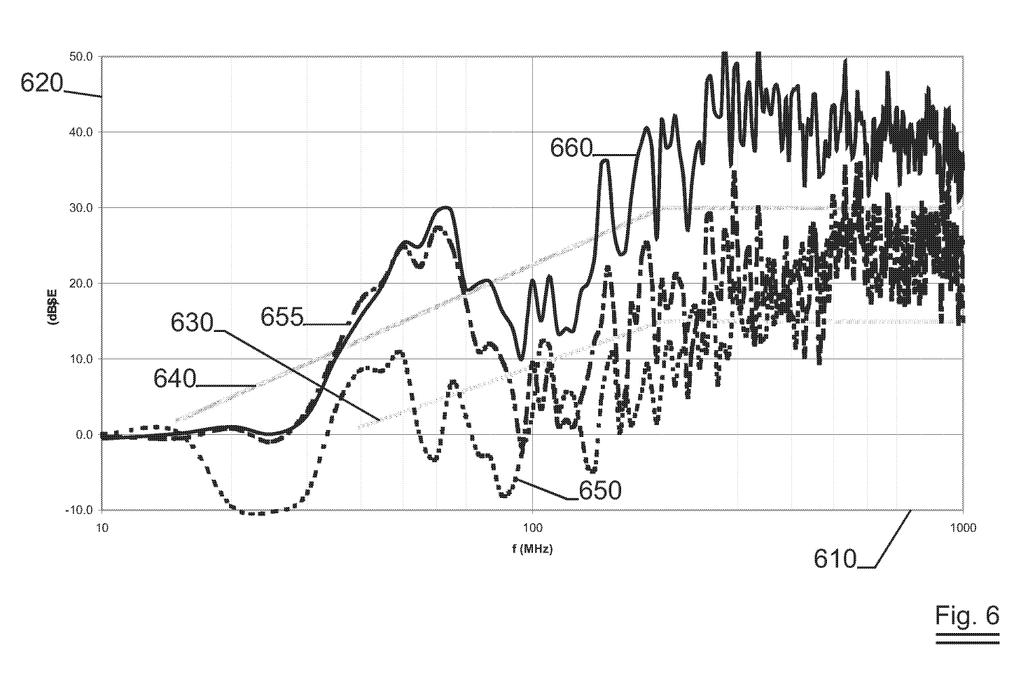

In FIG. 6 to 8 the results of the measurements are depicted over the measured frequency range. In this series of figures, the abscissa 610, 710, 810 always represents the frequency in MHz on a logarithmic scale and the ordinate 620, 720, 820 represents the SE in decibel (dB). The lines 630, 730, 830 represent the specification for what is called a 15 dB box. The lines 640, 740, 840 represent the specification for a 30 dB box.

In a first embodiment granules containing 75% by weight stainless steel fibres (the remainder being 25% by weight polymer material). The stainless steel fibres have an equivalent diameter of 8 μm and are 5 mm long. The fibres were made from AISI302 type of stainless steel. These were mixed into a masterbatch with PC granules so as to obtain 3% of stainless steel fibre by volume in the finished shell. A shell—in the form of a half box like the one depicted in FIG. 1 but without apertures—was injection molded from this mixture under optimised conditions for injection pressure, back pressure, injection speed, temperature and other process parameters: a procedure known to the person skilled in the art. The width of the shell was 3 mm. In a first attempt to make a joint, an overlap between the edges of the shell was implemented: at the borders, the mold was such that the thickness of the shell halved at 5 mm from the edges. Matching the two pieces together formed the joint that was subsequently measured: the results are indicated in FIG. 6 as the dotted line 650. Subsequently, the half edges were milled-off to uncover the conductive fibre at the borders: 3 mm areas were thus uncovered. Again a joint was made by placing the shells against one another. The measurement result of this joint are indicated as the dash-dot line 655 in FIG. 6. Subsequently a gasket (obtained from Schlegel with type number E62 5 3-xxx, 3.2 mm thick and 9.5 mm wide) was introduced in the joint and again the SE was measured: the solid line 660 shows the trace. It is obvious that the SE is improved by having the electrical fibres uncovered particularly in the frequency region between 30 and 100 MHz. The overlap joint suffers from a too high impedance in this frequency region. The best shielding efficiency over the largest frequency range is obtained by introducing a gasket. At frequencies above 300 MHz, the differences diminished as the capacitive coupling at the overlap diminishes the impedance at the joint, but the results with the gasket remain superior.

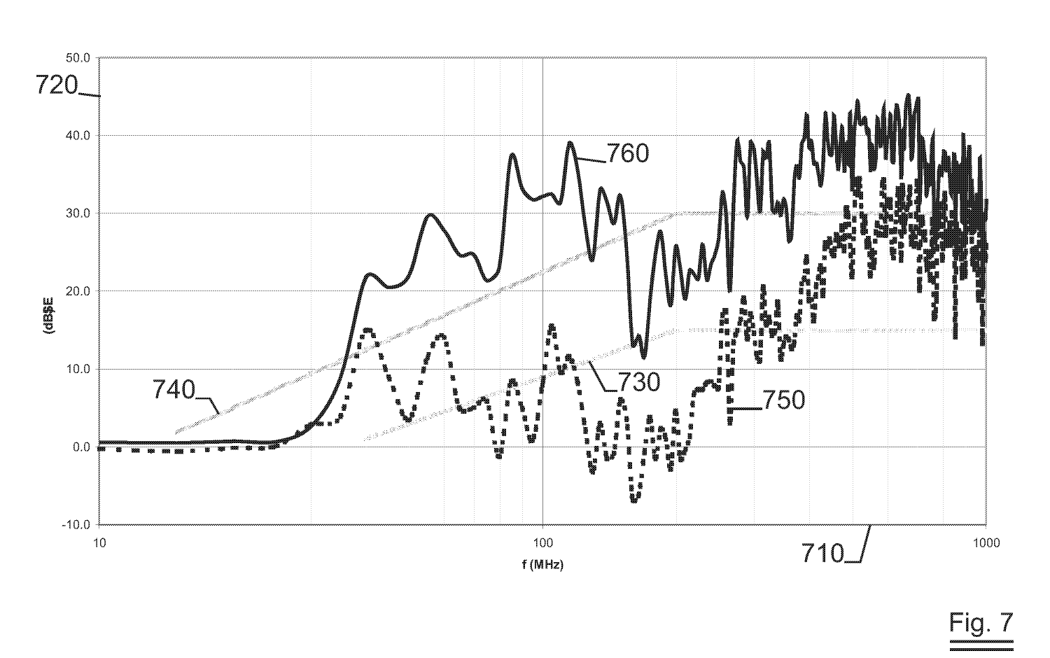

FIG. 7 depicts the results of a second embodiment. Test samples had the same dimensions and measurement procedures were identical as for the first embodiment. The difference with the previous embodiment is that now:
another type of fibres was used, namely the ones claimed in WO 03/010353 (AISI 302 HQ), and
the shells were injection molded from compound granules in stead of starting from a masterbatch mix.
uncovering was done by breaking-off the standing lips at the edges.
   Again the shielding efficiency was measured and is represented as 750 for the overlap joint and 760 for the uncovered fibres together with a gasket. The improvement is similar as to the first embodiment and better in the critical region between 30 and 300 MHz.

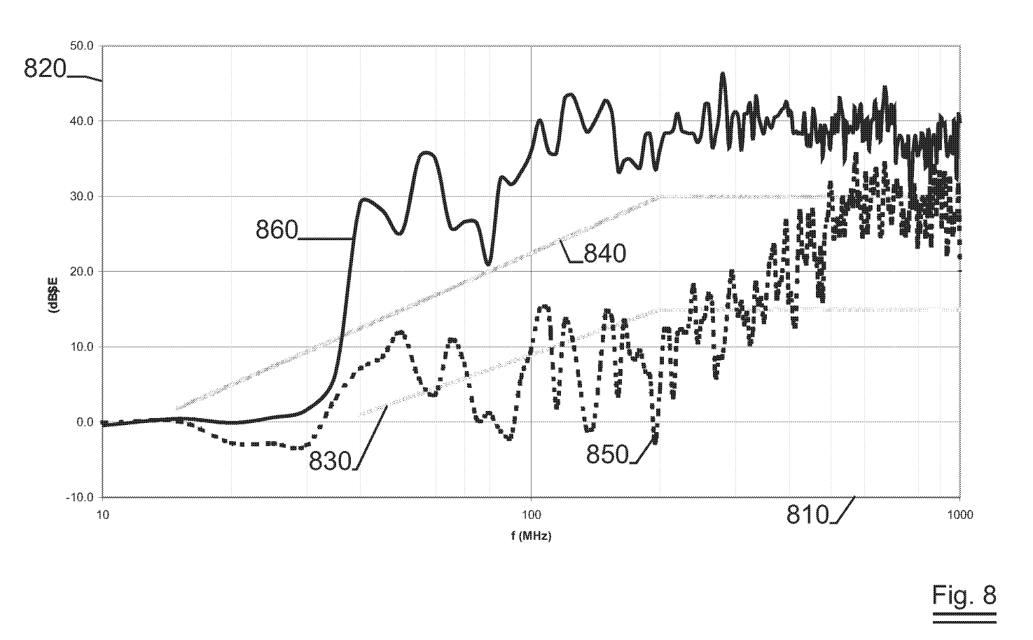

In a third embodiment, the results of which are represented in FIG. 8, a masterbatch was prepared by mixing fibre granules with PC and ABS polymer granules. The masterbatch contained 30% by weight stainless steel fibres of type AISI302 the remainder being the polyester jacket. Fibres have an equivalent diameter of 8 μm and a length of 5 mm. The volume concentration of fibres was raised to 6%. Again an overlap joint and a joint with uncovered fibres and a gasket were made and measured. Again the fibres were uncovered by breaking-off the lips. The results are shown in FIG. 8: 850 is the curve for an overlap and 860 is the curve for uncovered fibres in combination with the gasket. The influence of the increased fibre volume is obvious.

Besides the above three embodiments many others have been made and tested. With the other uncovering methods the following general results were obtained:
Scraping-off the polymer rich layer at the edges of the shell yields results that are on average 5 dB worse than the breaking-off uncovering.
Grinding the edges yields results equivalent to the breaking-off uncovering
Cutting the edges results in reduced available contact area because only the cross section of the fibre is contactable, and no protruding fibre is available. Due to this reduced contact the performance is less at lower frequencies
Milling the edges gives the worst results of all methods considered.
   Overall the method in which fibres are uncovered by breaking-off edges at predefined areas turned out to be the best and most practical method. Because the breakage at the edges always results in a minor burr that introduces minor unevenness at the joint, the method can be further improved by using a resilient conductive gasket at the joint that accommodates for this unevenness.

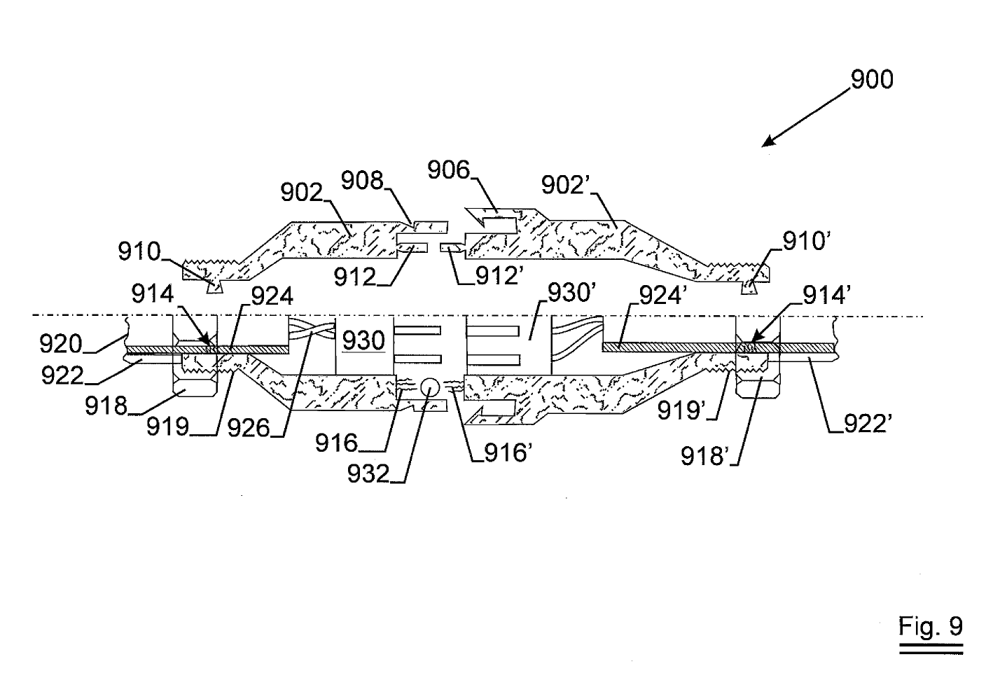

FIG. 9 shows a further preferred embodiment wherein the shielding housing is made in the form of a rotational symmetric plug and socket combination 900. Above the symmetry line of the drawing, a cross section of the plug and socket combination is shown as it is ejected from the injection molding machine. Below the symmetry line the combination is shown in its final form. Basically the combination consists of two injection molded parts 902 and 902′ that mechanically snap fit together by means of a clip 906 that engages into a recess 908. The tolerances are such that a good but detachable fit is obtained between the parts 902, 902′. At specific areas 910, 910′ and 912, 912′ protrusions are provided that are filled up with a polymer conductive fibre mix upon injection. Note that—due to the rotational symmetry of this embodiment, these protrusions have a ring shape. After injection molding, the rings 912, 912′ and 910, 910′ are broken off. Even better is, if the mold is so designed that the protrusions break off at the ejection phase of the molding cycle. Due to this action, the conductive fibres are unveiled and become visible at the surface: 916, 916′ and 914, 914′. The connector bodies 930, 930′—wherein the electrical connector pins and bushes are embodied—are inserted into the parts 902, 902′ after being connected with the wires 926 of the cable 920 that is to be connected. When the cable 920 is also provided with a shielding layer 924 under the insulation jacket 922, an electrical contact can easily be established between uncovered fibres 914, 914′ and the cable shielding 924, 924′. A tight contact between cable shield and connector can e.g. be established by bolting a nut 918, 918′ over the threaded end sections 919, 919′ of part 902, 902′. In case the end sections are provided with longitudinal slits the remaining tails will near each other when the bolt closes on the end section. In this way not only a good electrical contact is established between shielding and connector but also a strong mechanical grip between cable and connector. Finally a conductive annular gasket 932 may be provided between both connectors so as to improve the electrical connection between the annular areas 916, 916′ of this inventive connector pair.

In the now following claims, the true spirit and scope of the inventions is delineated, including all alterations and modifications that lie within the reach of the person skilled in the art.

1. A shielding shell comprising a polymeric material and electrically conductive fibres dispersed in said polymeric material, wherein on predefined areas on the surface of said shell, said conductive fibres are uncovered.

2. The shielding shell of claim 1 wherein said electrically conductive fibres are uncovered over one or more areas as to form at least one path on said surface.

3. The shielding shell according claim 1 wherein part of said uncovered electrically conductive fibres protrude out of the surface of said shell at said areas.

4. The shielding shell according claim 1 wherein said electrically conductive fibres comprise non-metallic fibres that are coated with a metal.

5. The shielding shell according claim 1 wherein said electrically conductive fibres comprise metallic fibres.

6. The shielding shell of claim 5 wherein said metallic fibres comprise stainless steel fibres.

7. The shielding shell according claim 5 wherein said metallic fibres have an equivalent diameter ranging between 1 μm to 50 μm and have an average length of between 0.5 and 50 mm.

8. The shielding shell according to claim 1 wherein said polymeric material is one selected out of the group consisting of polyolefines such as polypropylene (PP) or polyethylene (PE), polyvinylchloride (PVC), polystyrenes such as poly(acrylonitrile-butadiene-styrene) (ABS) or poly(styrene-acrylonitrile) (SAN) or High Impact polystyrene (HIPS), thermoplastic polyurethanes (TPU's), polyamides (PA's) such as PA 6 or PA 6.6, polyphenylene sulphide (PPS), polyesters such as polybutylene terephtalate (PBT), polyethylene terephtalate (PET), polyacetals such as polyoxymethylene (POM), polycarbonates (PC's), polysulfones (PSU's) such as polyethersulfone (PES), polyetherimides (PEI's), polyphenylene ethers (PPE) such as polyphenylene oxide (PPO®), Polyacrylics such polymethylmethacrylate (PMMA), meltable polyimides and polyamide-imides, polyetheretherketone (PEEK) and mixtures thereof.

9. The shielding shell according to claim 1 wherein said polymeric material is one selected out of the group consisting of polyolefines such as polypropylene (PP) or polyethylene (PE), polyvinylchloride (PVC), polystyrenes such as poly(acrylonitrile-butadiene-styrene) (ABS) or poly(styrene-acrylonitrile) (SAN) or High Impact polystyrene (HIPS), thermoplastic polyurethanes (TPU's), polyamides (PA's) such as PA 6 or PA 6.6, polyphenylene sulphide (PPS), polyesters such as polybutylene terephtalate (PBT), polyethylene terephtalate (PET), polyacetals such as polyoxymethylene (POM), polycarbonates (PC's), polysulfones (PSU's) such as polyethersulfone (PES), polyetherimides (PEI's), polyphenylene ethers (PPE) such as polyphenylene oxide (PPO®, Polyacrylics such polymethylmethacrylate (PMMA), meltable polyimides and polyamide-imides, polyetheretherketone (PEEK) and polymer blends comprising one or more of the above mentioned polymers.

10. A shielding housing comprising one or more shielding shells forming a housing when matched together wherein at least one of said shielding shells is a shell according to claim 1.

11. The shielding housing according claim 10 wherein said uncovered fibres of said predefined areas of said at least one shell electrically contact one or more of the shells.

12. The shielding housing according to claim 11 wherein said electrical contact is obtained by direct contact with said uncovered fibres.

13. The shielding housing according to claim or 11 wherein said electrical contact with said uncovered fibres is obtained through a gasket or a paste or a glue or a combination thereof.

14. The shielding housing according to claim 10 wherein said shielding shells form a pair of joinable and releasable connectors that match to one another.

15. A method to produce a shielding shell comprising the steps of:
providing a mixture comprising polymeric granules and electrically conductive fibres
injection-molding said mixture under the appropriate pressure and temperature in a mold having the negative form of said shell, said mold further defining protrusions or recesses on said shell.
uncovering said electrically conductive fibres at said protrusions or recesses.

16. The method of claim 15 wherein said mixture comprises polymeric granules and granules comprising electrically conductive fibres.

17. The method according to claim 15 wherein said step of uncovering the electrically conductive fibres is performed inside said mold before or during ejection of said shell.

18. The method according to claim 15 wherein said step of uncovering the electrically conductive fibres is performed by breaking said shell at said protrusions or recesses.

19. The method according to claim 15 wherein said step of uncovering the electrically conductive fibres is performed by any one method out of the group comprising cutting, grinding, buffing, filing, sawing, scraping, scratching or a combination thereof.
